(19) United States
(12) Patent Application Publication
(10) Pub. No.: US 2025/0125250 A1
(43) Pub. Date: Apr. 17, 2025

(54) LINE-VIA-LINE STRUCTURE FOR BSPDN

(71) Applicant: INTERNATIONAL BUSINESS MACHINES CORPORATION, ARMONK, NY (US)

(72) Inventors: Nicholas Anthony Lanzillo, Wynantskill, NY (US); Albert M. Chu, Nashua, NH (US); Reinaldo Vega, Mahopac, NY (US); Lawrence A. Clevenger, Saratoga Springs, NY (US); Ruilong Xie, Niskayuna, NY (US); Brent A. Anderson, Jericho, VT (US)

(21) Appl. No.: 18/485,346

(22) Filed: Oct. 12, 2023

(51) Int. Cl. H01L 23/522; H01L 21/768; H01L 23/528; H01L 23/532

(52) U.S. Cl. CPC H01L 23/5223; H01L 21/76802; H01L 21/76877; H01L 21/76885; H01L 23/5226; H01L 23/5283; H01L 23/5329

(57) ABSTRACT

Embodiments of present invention provide a semiconductor structure. The semiconductor structure includes a plurality of lower metal lines in a first metal level; a transition via directly on top of the plurality of lower metal lines; and an upper metal line directly on top of the transition via and the upper metal line being in a second metal level and orthogonal to the plurality of lower metal lines, where at least a first lower metal line of the plurality of lower metal lines has a recessed region and a rest region, the recessed region is directly underneath the transition via and filled with a dielectric material; and isolates the rest region of the first lower metal line from the transition via. A method of manufacturing the same is also provided.

### BACKGROUND

The present application relates to manufacturing of semiconductor integrated circuits. More particularly, it relates to a line-via-line structure and method of forming the same.

As semiconductor industry moves towards smaller nodes and more compact structures, some interconnects and signal routing functions, as well as power supplies are being moved from the frontside to the backside of the semiconductor chip. Generally, at the backside of the chip, interconnects may be formed to have one pitch, e.g., a first pitch, while backside power rails (BSPRs) such as those from the backside power distribution network (BSPDN) may be formed to have another pitch, e.g., a second pitch. Usually, the first pitch and the second pitch are dramatically different in terms of their size. Sometimes this difference may be as large as 8 to 9 times in value.

A transition via may be used as an intermediate medium that connects a wide metal line from the BSPDN to one or more narrow metal lines from the interconnect. To enable this connection scheme, some of the metal lines from the interconnect may be truncated in order to create spaces for the formation of, as well as not to get shorted by, the metal line from the BSPDN. Nevertheless, this truncation of metal lines usually results reduced usability of the interconnect.

### SUMMARY

Embodiments of present invention provide a semiconductor structure. The semiconductor structure includes a plurality of lower metal lines in a first metal level; a transition via directly on top of the plurality of lower metal lines; and an upper metal line directly on top of the transition via, the upper metal line being in a second metal level and orthogonal to the plurality of lower metal lines, where at least a first lower metal line of the plurality of lower metal lines has a recessed region and a rest region, the recessed region is directly underneath the transition via and filled with a dielectric material; and isolates the rest region of the first lower metal line from the transition via.

In one embodiment, the transition via is conductively connected to at least a second lower metal line of the plurality of lower metal lines.

In another embodiment, the upper metal line has a width that is about 9 times as wide as a width of the first lower metal line.

In one embodiment, the plurality of lower metal lines have a width of about 40 nm and a pitch of about 80 nm and the upper metal line has a width of about 360 nm, and wherein the transition via has a width of about 324 nm and a length of about 324 nm; and is directly above at least 4 of the plurality of lower metal lines.

In another embodiment, the recessed region of the first lower metal line has a length that is equal to or larger than a length of the transition via.

In one embodiment, the dielectric material in the recessed region of the first lower metal line is a high-k dielectric having a dielectric constant equal to or larger than 4.

According to one embodiment, the transition via and the first lower metal line, including the recessed region thereof, form a low pass decoupling capacitor.

Embodiments of present invention provide a semiconductor structure that includes a plurality of lower metal lines in a first metal level; a transition via directly on top of the plurality of lower metal lines; and an upper metal line on top of the transition via, the upper metal line being one of a plurality of upper metal lines in a second metal level, where at least a first and a second lower metal line of the plurality of lower metal lines each has a recessed region and a rest region, the recessed region is directly underneath the transition via and isolates the rest region of the first and the second lower metal line from the transition via.

In one embodiment, the transition via is conductively connected to at least a third lower metal line of the plurality of lower metal lines.

In another embodiment, the plurality of upper metal lines have a width of about 360 nm and a pitch of about 720 nm and the plurality of lower metal lines have a width of about 40 nm and a pitch of about 80 nm, and where the transition via has a width of about 324 nm and a length of about 324 nm; and is directly above at least 4 of the plurality of lower metal lines.

In one embodiment, the recessed region of the first lower metal line has a length of about 360 nm.

In another embodiment, the dielectric material in the recessed region of the first lower metal line is hafnium-oxide (HfO) having a dielectric constant larger than 4, and the transition via and the first lower metal line, including the recessed region of HfO, form a low pass decoupling capacitor.

Embodiments of present invention provide a method of forming a semiconductor structure. The method includes forming a plurality of lower metal lines of a first metal level in a substrate; recessing a portion of a first lower metal line of the plurality of lower metal lines to create a recessed region and a rest region of the first lower metal line; filling the recessed region of the first lower metal line with a dielectric material; forming a first dielectric layer on top of the first metal level and creating an opening in the first dielectric layer to expose the recessed region of the first lower metal line; filling the opening in the first dielectric layer with a conductive material to form a transition via; forming a second dielectric layer on top of the first dielectric layer and on top of the transition via; and forming one or more upper metal lines of a second metal level in the second dielectric layer.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, and 1C are demonstrative illustrations of a top view and cross-sectional views of a semiconductor structure according to one embodiment of present invention;

FIGS. 2A, 2B, and 2C to FIGS. 7A, 7B, and 7C are demonstrative illustrations of top views and cross-sectional views of a semiconductor structure in various steps of manufacturing thereof according to embodiments of present invention; and

FIG. 8 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

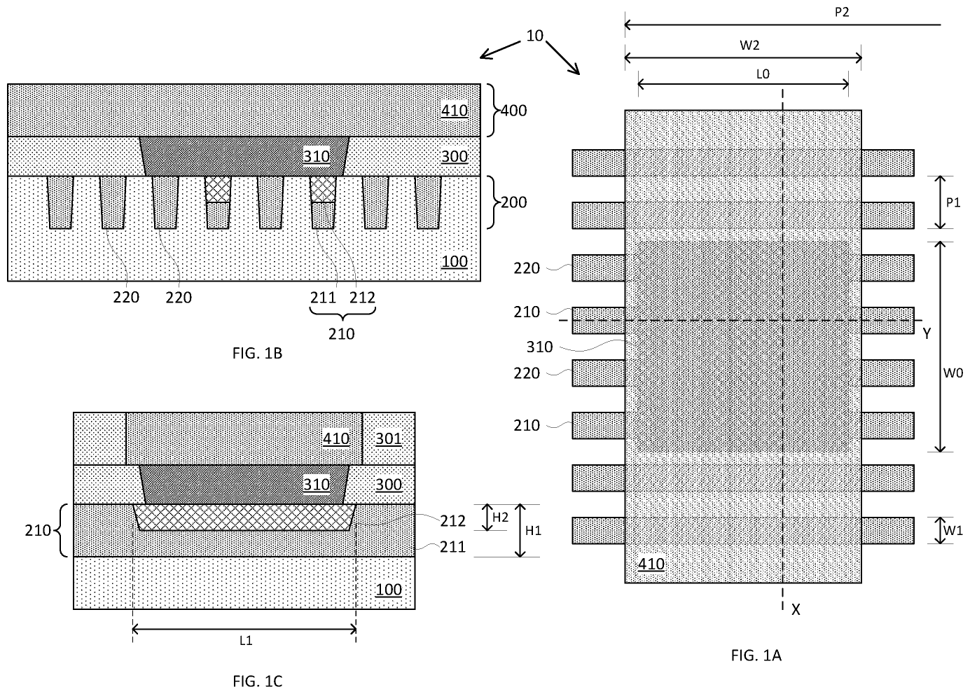

FIG. 1A is a demonstrative illustration of a top view and FIGS. 1B and 1C are demonstrative illustrations of cross-sectional views of a semiconductor structure according to one embodiment of present invention. More specifically, made along a dashed line X in FIG. 1A, FIG. 1B illustrates a cross-sectional view of the semiconductor structure across and along a width direction of one or more lower metal lines. Made along a dashed line Y in FIG. 1A, FIG. 1C illustrates a cross-sectional view of the semiconductor structure across and along a length direction of a lower metal line. Here, FIG. 1A selectively illustrates key elements such as the upper metal line, the plurality of lower metal lines, and a transition via. Other elements such as the surrounding dielectric materials are intentionally omitted in order not to overcrowd the drawing and hinder the illustration of embodiments of present invention.

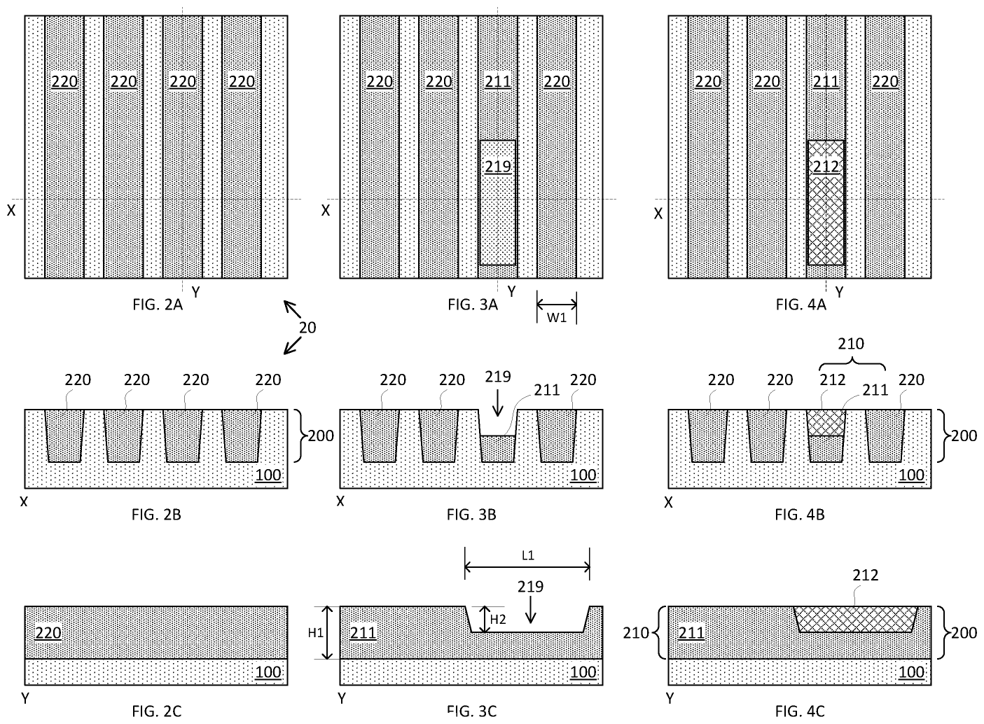

Likewise, FIGS. 2A, 2B, and 2C to FIGS. 7A, 7B, and 7C illustrate top views and cross-sectional views of the semiconductor structure, at various manufacturing stages, in manners similar to FIGS. 1A, 1B, and 1C respectively.

Embodiments of present invention provide a semiconductor structure 10. The semiconductor structure 10 includes a plurality of lower metal lines formed or embedded in a substrate 100. In one embodiment, the substrate 100 may simply be a supporting structure such as a layer of dielectric material or other suitable materials. The plurality of lower metal lines may be part of or may be formed in a first metal level 200 and may include a first group of one or more lower metal lines 210 and a second group of one or more lower metal lines 220. The first group of one or more metal lines 210 may each include a recessed region 212 that is filled with a dielectric material, and a rest region 211 of conductive material. The rest region 211 may have a first height H1 and the recessed region 212 may have a second height H2 and the second height H2 may be, for example, equal to or less than half of the first height H1. In one embodiment, the dielectric material filling the recessed region 212 may be a high-k dielectric material such as, for example, hafnium-oxide (HfO) that has a dielectric constant equal to or larger than 4. In one embodiment, the plurality of lower metal lines 210 and 220 may have a width W1 of about 40 nm, for example, and may have a pitch P1 of about 80 nm.

The semiconductor structure 10 may also include a transition via 310 directly on top of the plurality of lower metal lines 210 and 220. The transition via 310 may be formed or embedded in a first dielectric layer 300 and may be made of copper, cobalt, aluminum, or other suitable conductive materials. In one embodiment, the transition via may have a width W0 of about 324 nm, for example, and a length L0 of about 324 nm. In other words, the width W0 of the transition via 310 may be slightly larger than 4 times the pitch P1 of the lower metal lines 210 and 220 and therefore may be directly over at least 4 of the plurality of lower metal lines 210 and 220. On the other hand, the length L0 of the transition via 310 may be equal to or less than a length of the recessed region 212 of the lower metal line 210. For example, a length L1 of the recessed region 212 of the lower metal line 210 may be of about 360 nm, larger than 324 nm of the length L0 of the transition via 310.

The transition via 310 may be in conductive contact with, or conductively connected to, at least one of the second group of one or more lower metal lines 220 and may be isolated from at least one of the first group of one or more lower metal lines 210 by the respective recessed regions 212 of the lower metal lines 210. The second group of one or more lower metal lines 220 may be made of copper, cobalt, aluminum, or other suitable conductive materials, and so are the rest regions of the first group of one or more lower metal lines 210.

The semiconductor structure 10 may further include a second dielectric layer 301 and one or more upper metal lines such as an upper metal line 410 embedded in the second dielectric layer 301. The second dielectric layer 301 may be formed from a same dielectric material as that of the first dielectric layer 300. The one or more upper metal lines such as the upper metal line 410 may be made of copper, cobalt, aluminum, or other suitable material and may be formed in a second metal level 400. The one or more upper metal lines may be formed in a direction orthogonal to the direction of the lower metal lines, and in one embodiment may have a width W2 that is about 9 times larger than the width W1 of the lower metal lines such as the first group of lower metal lines 210 or the second group of lower metal lines 220. For example, the upper metal line 410 may have a width of about 360 nm while the lower metal lines 210 and 220 each may have a width of about 40 nm. The one or more upper metal lines may have a pitch of about 720 nm and may have a height of ranging from about 500 nm to about 1000 nm.

FIG. 2A is a demonstrative illustration of a top view and FIGS. 2B and 2C are demonstrative illustrations of cross-sectional views of a semiconductor structure in a step of manufacturing thereof according to one embodiment of present invention. More particularly, embodiments of present invention provide receiving or providing a supporting structure such as, for example, a substrate 100 and forming a first metal level 200 embedded in the substrate 100. In one embodiment, the supporting structure may be a dielectric layer such as a backside interlevel dielectric (BILD) layer. The first metal level 200 formed in the substrate 100 may include one or more lower metal lines 220 oriented in a first direction. In one embodiment, the one or more lower metal lines 220 may have a width of about 40 nm and a pitch of about 80 nm, and may be formed from copper, cobalt, aluminum, or other suitable conductive materials.

FIG. 3A is a demonstrative illustration of a top view and FIGS. 3B and 3C are demonstrative illustrations of cross-sectional views of a semiconductor structure in a step of manufacturing thereof according to one embodiment of present invention. More particularly, following the step illustrated in FIGS. 2A, 2B, and 2C, embodiments of present invention provide forming a recess 219 in one or more of the lower metal lines 220 of the first metal level 200. For example, a lithographic patterning process may be applied to expose a portion of the one or more of the lower metal lines 220, and the portion exposed may then be selectively etched to create the recess 219 having a height of H2. The lower metal lines 220 may have a height H1. In one embodiment, the height H2 of the recess 219 may be equal to or less than half of the height H1.

The recess 219 may widthwise truncate the one or more of the lower metal lines 220 to have a width of equal to or larger than that of the lower metal lines 220 and may have a length L1 that is equal to or longer than a length L0 of a transition via to be formed thereupon (see FIGS. 6A, 6B, and 6C). For example, in one embodiment, the length L1 of the recess 219 may be 360 nm when a transition via of 324 nm-by-324 nm is to be formed. The formation of the recess 219 in a lower metal line 220 may leave remaining portions of the lower metal line 220 to form or create a rest region 211.

FIG. 4A is a demonstrative illustration of a top view and FIGS. 4B and 4C are demonstrative illustrations of cross-sectional views of a semiconductor structure in a step of manufacturing thereof according to one embodiment of present invention. More particularly, following the step illustrated in FIGS. 3A, 3B, and 3C, embodiments of present invention provide filling the recess 219 of the one or more of the lower metal lines 220 with a dielectric material such as, for example, silicon-oxide or silicon-nitride to form a recessed region 212. For example, the dielectric material may be deposited in the recess 219 through a chemical-vapor-deposition (CVD) process, a physical-vapor-deposition (PVD) process, and/or an atomic-layer-deposition (ALD) process. A chemical-mechanical-polishing (CMP) process may subsequently be applied to planarize a top surface of the recessed region 212 such that it becomes co-planar with the rest region 211 and other lower metal lines 220. The recessed region 212 has a height H2 and a length L1, same as that of the recess 219.

In one embodiment, the dielectric material may be high-k dielectric such as hafnium-oxide (HfO) that has a dielectric constant larger than 4. The use of high-k dielectric such as HfO may help create a low-pass decoupling capacitor consisting of a transition via 310 (to be formed hereinafter, see FIGS. 6A, 6B, and 6C) and the lower metal line 210 that includes the recessed region 212 and the rest region 211.

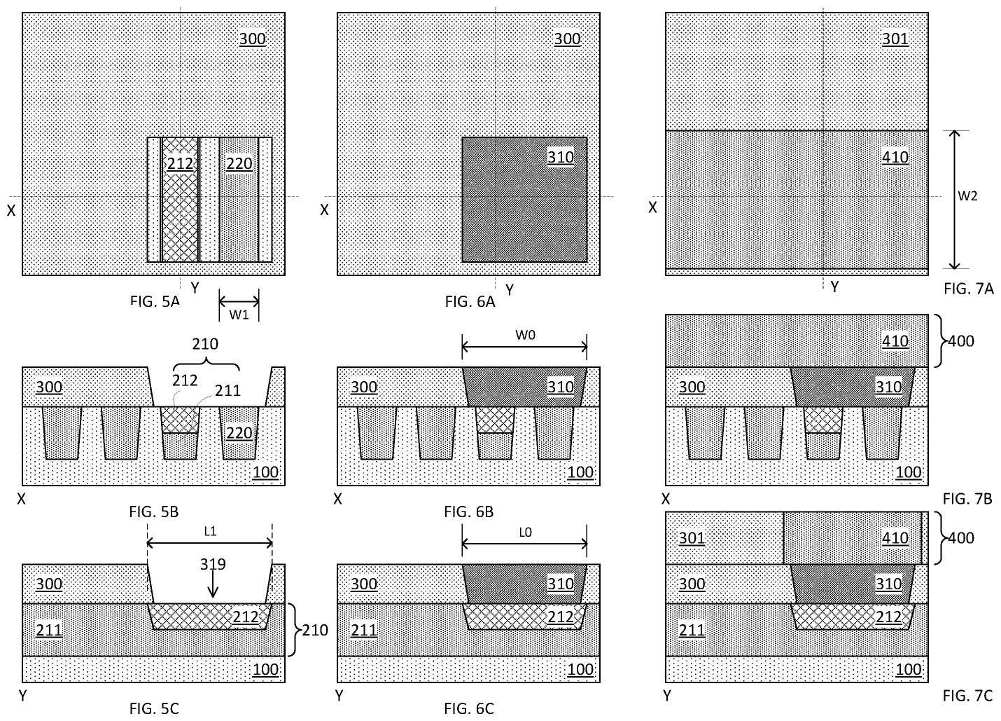

FIG. 5A is a demonstrative illustration of a top view and FIGS. 5B and 5C are demonstrative illustrations of cross-sectional views of a semiconductor structure in a step of manufacturing thereof according to one embodiment of present invention. More particularly, following the step illustrated in FIGS. 4A, 4B, and 4C, embodiments of present invention provide forming a first dielectric layer 300 on top of and covering the one or more lower metal lines 210 and 220 of the first metal level 200 in the substrate 100. The first dielectric layer 300 may be formed from, for example, silicon-oxide or silicon-nitride and have a thickness ranging from about 50 nm to about 500 nm.

Next, embodiments of present invention provide creating an opening 319 in the first dielectric layer 300 to expose portions of one or more of the lower metal lines 210 and 220 in the first metal level 200. The opening 319 may have a width W0 that ranges across several of the lower metal lines 210 and 220. For example, in one embodiment, the width W1 of the lower metal lines 210 and 220 may be about 40 nm, with a pitch of about 80 nm, and the width W0 of the opening 319 may be about 324 nm. In other words, the opening 319 may expose 4 of the lower metal lines 210 and 220. In another embodiment, the opening 319 may be in a shape of square and thus may have a length L0 that equals to the width W0. For example, the length L0 of the opening 319 may be about 324 nm. The opening 319 may be formed to have a length L0 shorter than the length L1 of the recessed region 212 of the lower metal line 210 and used to form a transition via as being described below in more details.

FIG. 6A is a demonstrative illustration of a top view and FIGS. 6B and 6C are demonstrative illustrations of cross-sectional views of a semiconductor structure in a step of manufacturing thereof according to one embodiment of present invention. More particularly, following the step illustrated in FIGS. 5A, 5B, and 5C, embodiments of present invention provide filling the opening 319 with a conductive material such as, for example, copper, cobalt, aluminum, or other suitable materials, to form a transition via 310. As being described above with regard to the opening 319, the transition via 310 may have a width W0 and a length L0. The width W0 may be wide enough to expose several of the lower metal lines and in particular may expose at least the recessed region 212 of one of the lower metal lines 210 and at least one lower metal line 220. The length L0 of the transition via 310 may be equal or less than the length L1 of the recessed region 212.

FIG. 7A is a demonstrative illustration of a top view and FIGS. 7B and 7C are demonstrative illustrations of cross-sectional views of a semiconductor structure in a step of manufacturing thereof according to one embodiment of present invention. More particularly, following the step illustrated in FIGS. 6A, 6B, and 6C, embodiments of present invention provide forming a second dielectric layer 301 on top of the first dielectric layer 300 and over the transition via 310. In one embodiment, the first dielectric layer 300 and the second dielectric layer 301 may be formed from a same dielectric material. Next, embodiments of present invention provide forming one or more upper metal lines such as an upper metal line 410 in the second dielectric layer 301. The one or more upper metal lines may be formed through a damascene process or a subtractive patterning process and may form a second metal level 400. The second metal level 400 may be in a second direction that is orthogonal to the first direction of the first metal level 200. A CMP process may be optionally applied to planarize a top surface of the one or more upper metal lines to be coplanar with a top surface of the second dielectric layer 301.

In one embodiment, the one or more upper metal lines may have a width W2 that is equal to or larger than the length L0 of the transition via 310 and may be formed directly on top of the transition via 310. For example, the upper metal line 410 may have a width of about 360 nm, when the transition via has a length L0 of about 324 nm and the lower metal lines 210 and 220 have a width W1 of about 40 nm and a pitch of about 80 nm. In other words, the upper metal line 410 may have a width W2 that is about 9 times larger than the width W1 of the lower metal lines 210 and 220. In one embodiment, the one or more upper metal lines may have a pitch of about 720 nm.

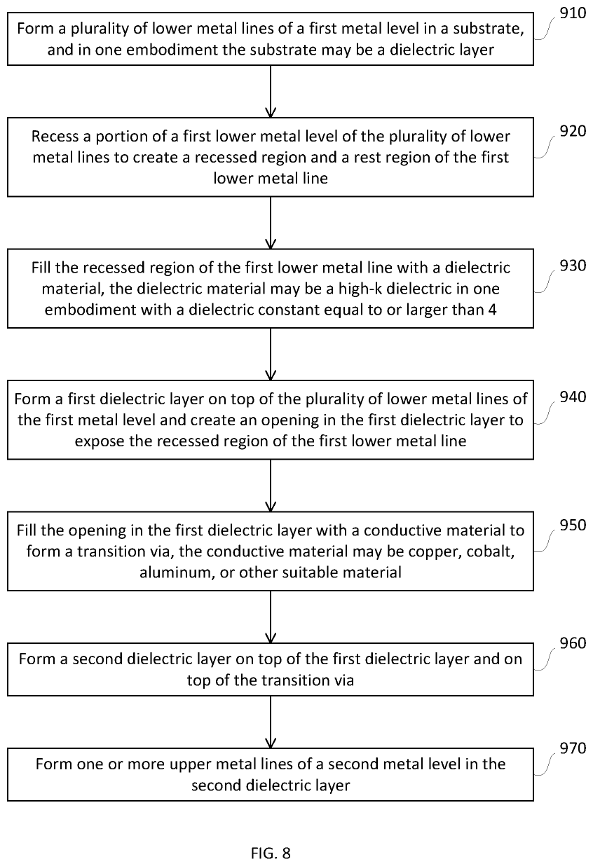

FIG. 8 is a demonstrative illustration of a flow-chart of a method of manufacturing a semiconductor structure according to embodiments of present invention. The method includes (910) forming a plurality of lower metal lines of a first metal level in a substrate, and in one embodiment the substrate may be a dielectric layer; (920) recessing a portion of a first lower metal level of the plurality of lower metal lines to create a recessed region and a rest region of the first lower metal line; (930) filling the recessed region of the first lower metal line with a dielectric material, the dielectric material may be a high-k dielectric in one embodiment with a dielectric constant equal to or larger than 4; (940) forming a first dielectric layer on top of the plurality of lower metal lines of the first metal level and creating an opening in the first dielectric layer to expose the recessed region of the first lower metal line; (950) filling the opening in the first dielectric layer with a conductive material to form a transition via, the conductive material may be copper, cobalt, aluminum, or other suitable material; (960) forming a second dielectric layer on top of the first dielectric layer and on top of the transition via; and (970) forming one or more upper metal lines of a second metal level in the second dielectric layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a plurality of lower metal lines in a first metal level;
a transition via directly on top of the plurality of lower metal lines; and
an upper metal line directly on top of the transition via, the upper metal line being in a second metal level and orthogonal to the plurality of lower metal lines,
wherein at least a first lower metal line of the plurality of lower metal lines has a recessed region and a rest region, the recessed region is directly underneath the transition via and filled with a dielectric material; and isolates the rest region of the first lower metal line from the transition via.

2. The semiconductor structure of claim 1, wherein the transition via is conductively connected to at least a second lower metal line of the plurality of lower metal lines.

3. The semiconductor structure of claim 1, wherein the upper metal line has a width that is about 9 times as wide as a width of the first lower metal line.

4. The semiconductor structure of claim 1, wherein the plurality of lower metal lines have a width of about 40 nm and a pitch of about 80 nm and the upper metal line has a width of about 360 nm, and wherein the transition via has a width of about 324 nm and a length of about 324 nm; and is directly above at least 4 of the plurality of lower metal lines.

5. The semiconductor structure of claim 1, wherein the recessed region of the first lower metal line has a length that is equal to or larger than a length of the transition via.

6. The semiconductor structure of claim 1, wherein the dielectric material in the recessed region of the first lower metal line is a high-k dielectric having a dielectric constant equal to or larger than 4.

7. The semiconductor structure of claim 6, wherein the transition via and the first lower metal line, including the recessed region thereof, form a low pass decoupling capacitor.

8. A semiconductor structure comprising:
a plurality of lower metal lines in a first metal level;
a transition via directly on top of the plurality of lower metal lines; and
an upper metal line on top of the transition via, the upper metal line being one of a plurality of upper metal lines in a second metal level,
wherein at least a first and a second lower metal line of the plurality of lower metal lines each has a recessed region and a rest region, the recessed region is directly underneath the transition via and isolates the rest region of the first and the second lower metal line from the transition via.

9. The semiconductor structure of claim 8, wherein the transition via is conductively connected to at least a third lower metal line of the plurality of lower metal lines.

10. The semiconductor structure of claim 8, wherein the upper metal line has a width that is about 9 times as wide as a width of the first lower metal line.

11. The semiconductor structure of claim 8, wherein the plurality of upper metal lines have a width of about 360 nm and a pitch of about 720 nm and the plurality of lower metal lines have a width of about 40 nm and a pitch of about 80 nm, and wherein the transition via has a width of about 324 nm and a length of about 324 nm; and is directly above at least 4 of the plurality of lower metal lines.

12. The semiconductor structure of claim 11, wherein the recessed region of the first lower metal line has a length of about 360 nm.

13. The semiconductor structure of claim 11, wherein the dielectric material in the recessed region of the first lower metal line is hafnium-oxide (HfO) having a dielectric constant larger than 4, and the transition via and the first lower metal line, including the recessed region of HfO, form a low pass decoupling capacitor.

14. A method of forming a semiconductor structure comprising:
forming a plurality of lower metal lines of a first metal level in a substrate;
recessing a portion of a first lower metal line of the plurality of lower metal lines to create a recessed region and a rest region of the first lower metal line;
filling the recessed region of the first lower metal line with a dielectric material;
forming a first dielectric layer on top of the first metal level and creating an opening in the first dielectric layer to expose the recessed region of the first lower metal line;
filling the opening in the first dielectric layer with a conductive material to form a transition via;
forming a second dielectric layer on top of the first dielectric layer and on top of the transition via; and
forming one or more upper metal lines of a second metal level in the second dielectric layer.

15. The method of claim 14, wherein the opening created in the first dielectric layer exposes a second lower metal line of the plurality of lower metal lines.

16. The method of claim 15, wherein the transition via is isolated from the rest region of the first lower metal line by the recessed region and is conductively connected to the second lower metal line.

17. The method of claim 14, wherein the one or more upper metal lines have a width of about 360 nm and a pitch of about 720 nm, and the plurality of lower metal lines have a width of about 40 nm and a pitch of about 80 nm.

18. The method of claim 17, wherein creating the opening in the first dielectric layer comprises create the opening to expose at least 4 of the plurality of lower metal lines.

19. The method of claim 14, wherein recessing the portion of the first lower metal line comprises selectively etching the portion of the first lower metal line to create a recess such that the recess has a height that is equal to or less than half of a height of the first lower metal line.

20. The method of claim 14, wherein recessing the portion of the first lower metal line comprises selectively etching the portion of the first lower metal line to create a recess such that the recess has a length that is equal to or longer than a length of the transition via.
